(19) United States
(12) Patent Application Publication
(10) Pub. No.: US 2022/0285481 A1
(43) Pub. Date: Sep. 8, 2022

(54) SEMICONDUCTOR STRUCTURE AND FORMING METHOD THEREOF

(71) Applicant: CHANGXIN MEMORY TECHNOLOGIES, INC., Hefei City (CN)

(72) Inventors: Kangshu ZHAN, Hefei City (CN); Qiang WAN, Hefei City (CN); Penghui XU, Hefei City (CN); Tao LIU, Hefei City (CN); Sen LI, Hefei City (CN); Jun XIA, Hefei City (CN)

(73) Assignee: CHANGXIN MEMORY TECHNOLOGIES, INC., Hefei City (CN)

(21) Appl. No.: 17/445,609

(22) Filed: Aug. 22, 2021

Related U.S. Application Data
(63) Continuation of application No. PCT/CN2021/103574, filed on Jun. 30, 2021.

(30) Foreign Application Priority Data
Mar. 5, 2021 (CN) 202110244158.3

(51) Int. Cl. H01L 49/02

(52) U.S. Cl. CPC H01L 28/91; H01L 28/92; H01L 27/108

(57) ABSTRACT

A method for forming a semiconductor structure includes: forming a base including a substrate, capacitor contacts in the substrate, a laminated structure disposed on a surface of the substrate capacitor holes penetrating through the laminated structure and exposing the respective capacitor contacts, the laminated structure including a plurality of support layers and at least one sacrificial layer which are alternately stacked along a direction perpendicular to the substrate, and a lower electrode layer covering inner walls of the capacitor holes; forming a protective layer covering a surface of the lower electrode layer; etching part of the support layer to expose the sacrificial layer; and removing all the sacrificial layers and all the protective layer to expose the lower electrode layer.

### CROSS-REFERENCE TO RELATED APPLICATIONS

The present application is a continuation of International Patent Application No. PCT/CN2021/103574 filed on Jun. 30, 2021, which claims priority to Chinese Patent Application No. 202110244158.3 filed on Mar. 5, 2021. The disclosures of these applications are hereby incorporated by reference in their entirety.

### BACKGROUND

A Dynamic Random Access Memory (DRAM) is a semiconductor structure commonly used in an electronic device such as a computer, which is composed of a plurality of storage units each usually including a transistor and a capacitor. A gate of the transistor is electrically connected to a word line, a source of the transistor is electrically connected to a bit line, and a drain of the transistor is electrically connected to the capacitor. A word line voltage on the word line can control the on and off of the transistor, so that data information stored in the capacitor can be read from or written into the capacitor through the bit line.

### SUMMARY

The present disclosure relates generally to the technical field of semiconductor manufacturing, and more specifically to a semiconductor structure and a forming method thereof.

The present disclosure provides a method for forming a semiconductor structure, including steps of: forming a base including a substrate, capacitor contacts in the substrate, a laminated structure disposed on a surface of the substrate capacitor holes penetrating through the laminated structure and exposing the respective capacitor contacts, and a lower electrode layer covering inner walls of the capacitor holes; the laminated structure including a plurality of support layers and at least one sacrificial layer which are alternately stacked along a direction perpendicular to the substrate; forming a protective layer covering a surface of the lower electrode layer; etching part of the support layer to expose the sacrificial layer; and removing all the sacrificial layers and all the protective layer to expose the lower electrode layer.

The present disclosure also provides a semiconductor structure including: a substrate having a plurality of capacitor contacts therein; a laminated structure on a surface of the substrate, the laminated structure including a plurality of support layers stacked along a direction perpendicular to the substrate; a plurality of capacitor holes, penetrating through the laminated structure along the direction perpendicular to the substrate and exposing the respective capacitor contacts; and a plurality of lower electrode layers, covering inner walls of the respective capacitor holes, an etching window being provided between at least two adjacent lower electrode layers, the etching window having part of the support layer connected to the lower electrode layers on a side wall of the etching window, and the etching window being communicated with a gap region between the two adjacent lower electrode layers.

### BRIEF DESCRIPTION OF THE DRAWINGS

FIG. 1 is a flowchart of a method for forming a semiconductor structure according to some embodiments of the present disclosure.

FIG. 2A is a first schematic cross-sectional view of a main process in forming a semiconductor structure according to some embodiments of the present disclosure.

FIG. 2B is a second schematic cross-sectional view of a main process in forming a semiconductor structure according to some embodiments of the present disclosure.

FIG. 2C is a third schematic cross-sectional view of a main process in forming a semiconductor structure according to some embodiments of the present disclosure.

FIG. 2D is a fourth schematic cross-sectional view of a main process in forming a semiconductor structure according to some embodiments of the present disclosure.

FIG. 2E is a fifth schematic cross-sectional view of a main process in forming a semiconductor structure according to some embodiments of the present disclosure.

FIG. 2F is a sixth schematic cross-sectional view of a main process in forming a semiconductor structure according to some embodiments of the present disclosure.

FIG. 2G is a seventh schematic cross-sectional view of a main process in forming a semiconductor structure according to some embodiments of the present disclosure.

FIG. 2H is an eighth schematic cross-sectional view of a main process in forming a semiconductor structure according to some embodiments of the present disclosure.

### DETAILED DESCRIPTION

A typical manufacturing process of the capacitor in the DRAM usually includes the following operations. After a laminated structure in which a plurality of support layers and sacrificial layers are alternately stacked is formed, the laminated structure is etched to form capacitor holes. Thereafter, lower electrodes are formed in the respective capacitor holes. Next, the support layer in the middle of the laminated structure is opened through an etching process to remove the sacrificial layer in the laminated structure. However, in the process of opening the support layer in the middle of the laminated structure through the etching process, a lower electrode layer is easily damaged, so that an opening is formed in the lower electrode. Finally, the reliability of a DRAM device is deteriorated, and even the DRAM device fails seriously and is scrapped.

Various embodiments of the present disclosure can address how to avoid damages to the lower electrode when opening the support layer in the middle of the laminated structure and ensure the appearance integrity of the lower electrode so as to ensure the performance reliability of a final product.

Specific embodiments of a semiconductor structure and a forming method thereof provided by the present disclosure are described in detail below with reference to the accompanying drawings.

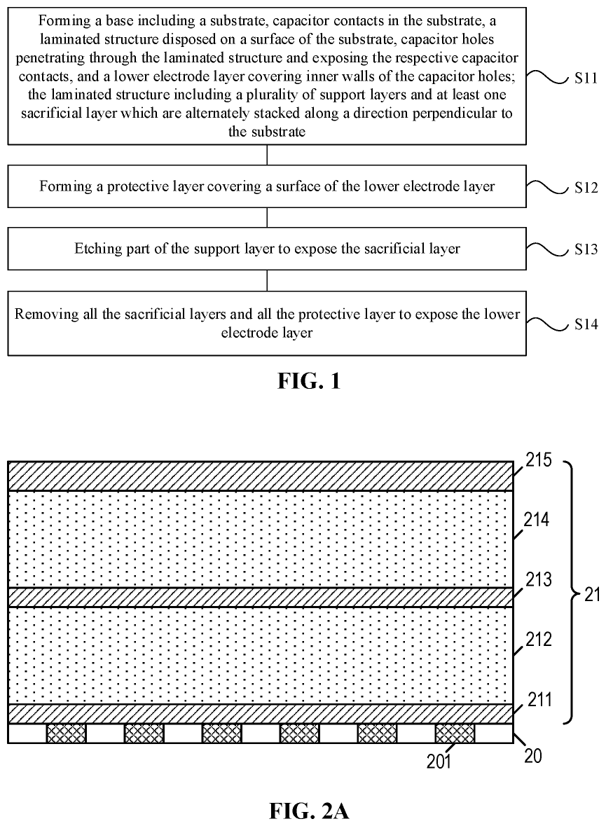

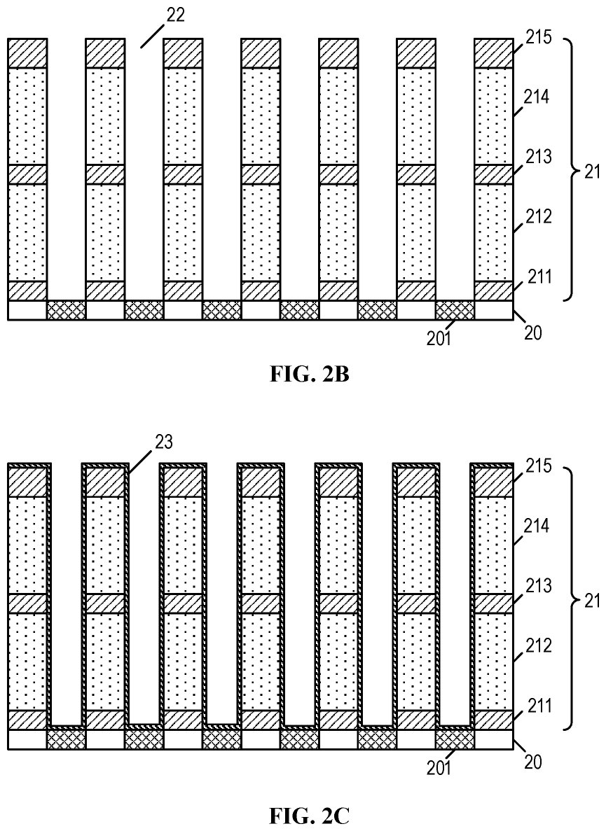

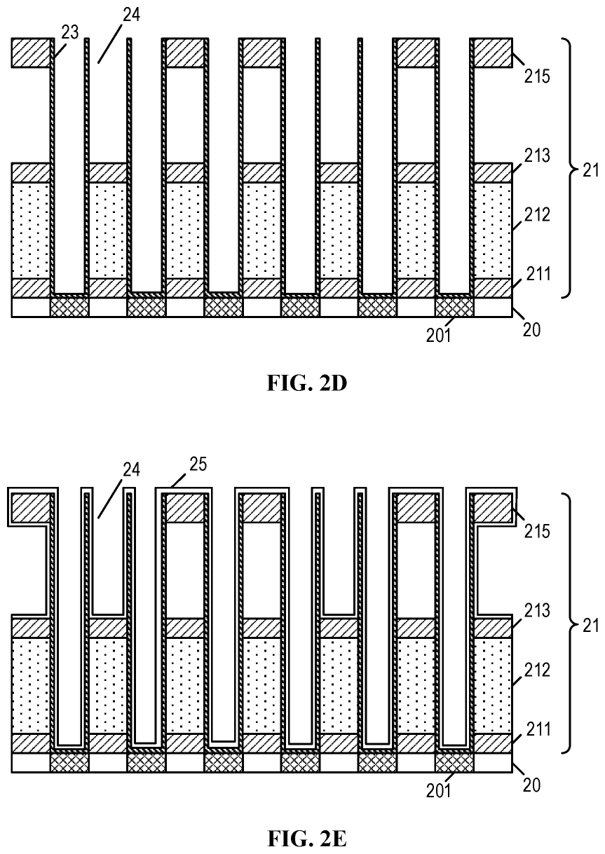

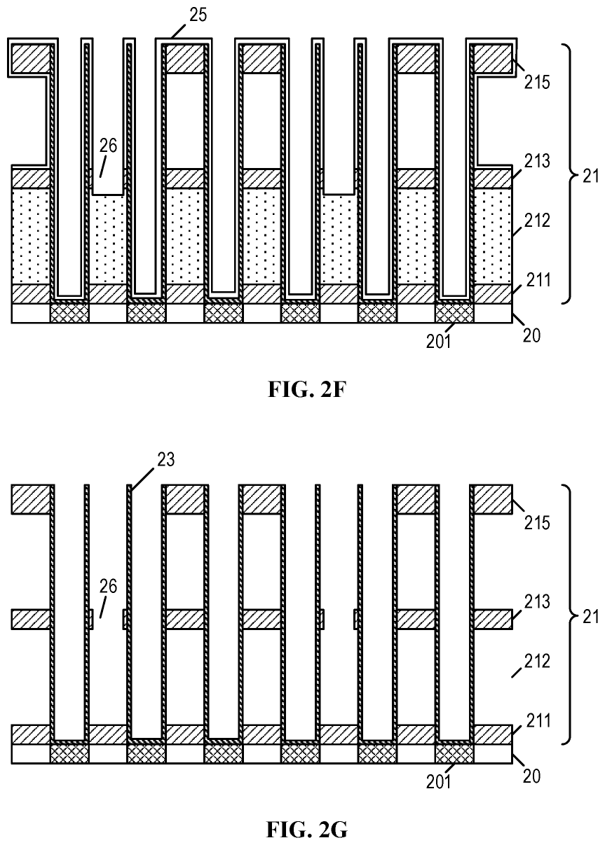

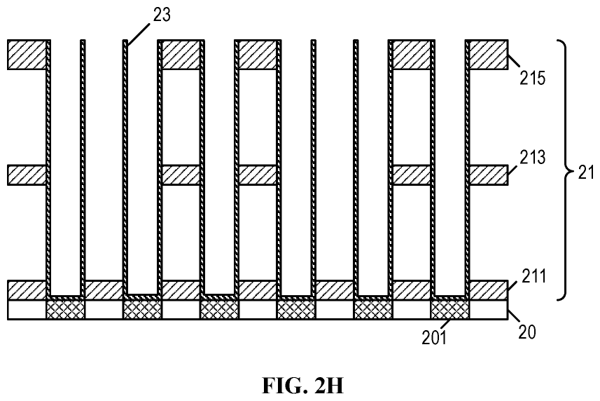

Various embodiments of the present disclosure provides a method for forming a semiconductor structure. FIG. 1 is a flowchart of a method for forming a semiconductor structure according to some embodiments of the present disclosure. FIGS. 2A-2H are schematic cross-sectional views of a main process in forming a semiconductor structure according to some embodiments of the present disclosure. As illustrated in FIGS. 1 and 2A-2H, the method for forming the semiconductor structure provided by the present specific embodiment includes the following steps.

In step S11, a base is formed. The base includes a substrate 20, capacitor contacts 201 in the substrate 20, a laminated structure 21 on a surface of the substrate 20, capacitor holes 22 penetrating through the laminated structure 21 and exposing the respective capacitor contacts 201, and a lower electrode layer 23 covering inner walls of the respective capacitor holes 22. The laminated structure 21 includes a plurality of support layers and at least one sacrificial layer which are alternately stacked along a direction perpendicular to the substrate 20, as illustrated in FIGS. 2B, 2C, and 2D.

Specifically, the substrate 20 may be, but is not limited to, a silicon substrate or a polycrystalline silicon substrate. The substrate 20 is illustrated in the present specific embodiment as a silicon substrate. The substrate 20 is configured to support a device structure thereon. In other examples, the substrate 20 may be a semiconductor substrate such as gallium nitride, gallium arsenide, gallium carbide, silicon carbide, or SOI. The substrate 20 may be a single-layer substrate or a multi-layer substrate formed by stacking a plurality of semiconductors, and a person skilled in the art would be able to choose according to practical requirements. The substrate 20 has a plurality of active areas arranged in an array therein, and the plurality of capacitor contacts 201 are electrically connected to the plurality of active areas.

Optionally, the specific step of forming a base includes the following operations.

A substrate 20 is provided. The substrate 20 has a plurality of capacitor contacts 201 therein.

A laminated structure 21 is formed on a surface of the substrate 20. The laminated structure 21 includes a first support layer 211, a first sacrificial layer 212, a second support layer 213, a second sacrificial layer 214, and a third support layer 215 which are sequentially stacked along a direction perpendicular to the substrate 20, as illustrated in FIG. 2A.

The laminated structure 21 is etched to form capacitor holes 22 penetrating through the laminated structure 21 along the direction perpendicular to the substrate 20 and exposing the respective capacitor contacts 201, as illustrated in FIG. 2B.

A lower electrode layer 23 covering inner walls of the respective capacitor hole 22 is formed, as illustrated in FIG. 2C.

Specifically, the first support layer 211, the first sacrificial layer 212, the second support layer 213, the second sacrificial layer 214, and the third support layer 215 are sequentially deposited on the surface of the substrate 20 by adopting a chemical vapor deposition process, a physical vapor deposition process, or an atomic layer deposition process to form the laminated structure 21 formed by alternately stacking support layers and sacrificial layers. The laminated structure 21 including three support layers and two sacrificial layers is illustrated in the present specific embodiment, and a person skilled in the art would be able to set the number of layers in which the support layers and the sacrificial layers are alternately stacked according to practical requirements. The first support layer 211, the second support layer 213, and the third support layer 215 may adopt the same material, for example, a nitride material (e.g., silicon nitride). The first sacrificial layer 212 and the second sacrificial layer 214 may also adopt the same material, for example, an oxide material (e.g., silicon oxide).

Thereafter, the laminated structure 21 is etched to form a plurality of capacitor holes 22 penetrating through the laminated structure 21 along the direction perpendicular to the substrate 20 and exposing the capacitor contacts 201. Next, conductive materials such as TiN are deposited on an inner wall of the capacitor hole 22 and a top surface of the third support layer 215 (i.e., a surface of the third support layer 215 away from the substrate 20) to form the lower electrode layer 23. A bottom surface of the lower electrode layer 23 is in contact connection with the capacitor contact 201.

Optionally, after the lower electrode layer 23 covering the inner walls of the capacitor holes 22 is formed, the method further includes the following steps.

Part of the third support layer 215 is etched to expose the second sacrificial layer 214.

The second sacrificial layer 214 is removed to expose part of the second support layer 213.

Specifically, after the lower electrode layer 23 covering the inner walls of the capacitor holes 22 and the top surface of the third support layer 215, the lower electrode layer 23 covering the top surface of the third support layer 215 is removed. Thereafter, a photoresist layer is formed on the surface of the third support layer 215, and the photoresist layer has openings therein exposing the third support layer 215. One of the openings overlaps one or more of the capacitor holes 22. Thereafter, part of the third support layer 215 is etched along the opening to expose the second sacrificial layer 214. Next, all of the second sacrificial layers 214 are removed by adopting a wet etching process, etc., and the second support layer 213 is exposed to form a structure as illustrated in FIG. 2D.

In step S12, a protective layer 25 covering a surface of the lower electrode layer 23 is formed, as illustrated in FIG. 2E.

Optionally, the specific step of forming the protective layer 25 covering the surface of the lower electrode layer 23 includes the following operations.

Protective materials are deposited on surfaces of the lower electrode layer 23, the remaining third support layer 215, and the exposed second support layer 213 to form the protective layer 25.

Optionally, the specific step of forming the protective layer 25 covering the surface of the lower electrode layer 23 further includes the following operations.

The protective layer 25 is formed by adopting an in-situ atomic layer deposition process.

Specifically, after the structure as illustrated in FIG. 2D is formed, protective materials are deposited on surfaces of the lower electrode layer 23, the remaining third support layer 215, and the exposed second support layer 213 to form the protective layer 25 by adopting an in-situ atomic layer deposition process. The protective layer 25 wraps the exposed surface of the lower electrode layer 23. On one hand, the lower electrode layer 23 with a large height and a small thickness can be supported, so that inclination or collapse of the lower electrode layer 23 in a subsequent process is avoided. On the other hand, the lower electrode layer 23 is separated from an etching agent subsequently used for etching the second support layer 213, so that the lower electrode layer 23 is prevented from being damaged in the process of opening the second support layer 213, the appearance integrity of the lower electrode layer 23 is ensured, and defects in the lower electrode layer 23 are avoided.

The protective layer 25 is formed by adopting an in-situ atomic layer deposition process in the present specific embodiment, so that the formed protective layer 25 can be ensured to be high in compactness and good in thickness uniformity, and the protective effect of the protective layer 25 on the lower electrode layer 23 is further improved. The protective layer 25 may also be formed in other ways by a person skilled in the art according to practical requirements.

In step S13, part of the support layer is etched to expose the sacrificial layer.

Optionally, the specific step of exposing part of the support layer includes the following operations.

The protective layer 25 between the adjacent capacitor holes 22 is etched to expose part of the second support layer 213.

Optionally, the specific step of etching the protective layer 25 between the adjacent capacitor holes 22 includes the following operations.

The protective layer 25 between the adjacent capacitor holes 22 is etched along a direction perpendicular to the substrate 20.

Optionally, after part of the second support layer 213 is exposed, the method further includes the following step.

The second support layer 213 is etched along a direction perpendicular to the substrate 20 to expose the first sacrificial layer 212.

Specifically, after the protective layer 25 is formed, the protective layer 25 and the second support layer 213 in a gap region 24 between the adjacent capacitor holes 22 are etched along a direction perpendicular to the substrate 20. Specifically, the protective layer 25 and the second support layer 213 at the bottom of the gap region 24 are etched to expose the first sacrificial layer 212. The protective layer 25 and the second support layer 213 at the bottom of the gap region 24 may be synchronously etched by adopting an appropriate etching reagent. Or, it is also possible to etch step by step, i.e. the protective layer 25 is opened in first etching and the second support layer 213 is opened in second etching. In the present specific embodiment, the protective layer 25 and the second support layer 213 are directly bombarded along a direction perpendicular to the substrate 20 in a directional etching mode, so that the lateral protective layer 25 is prevented from being damaged, thereby further improving the protective effect on the lower electrode layer 23.

Optionally, the specific step of etching the second support layer 213 along a direction perpendicular to the substrate 20 includes the following operations.

The second support layer 213 is etched along a direction perpendicular to the substrate 20, etching windows 26 exposing the first sacrificial layer 212 is formed in the second support layer 213, and the second support layer 213 is remained on side walls of the respective etching windows 26, as illustrated in FIG. 2F.

Specifically, after adopting directional etching, etching windows 26 exposing the first sacrificial layer 212 is formed in the second support layer 213, the second support layer 213 is remained on side walls of the respective etching windows 26, and a thickness of the remaining second support layer 213 in a radial direction of the capacitor hole 22 is smaller than or equal to that of the protective layer 25 in the radial direction of the capacitor hole 22. The second support layer 213 remained on the side walls of the respective etching windows 26 can support the lower electrode layer 23 without subsequent removal.

In step S14, all the sacrificial layers and all the protective layers 25 are removed to expose the lower electrode layer 23.

Optionally, the protective layer 25 and the first sacrificial layer 212 adopt the same material. The specific step of removing all the sacrificial layers and all the protective layers includes the following operation.

The first sacrificial layer 212 and the protective layer 25 are synchronously removed.

For example, the material of the protective layer 25 and the material of the first sacrificial layer 212 are both oxide materials. After the first sacrificial layer 212 is exposed, the protective layer 25 and the first sacrificial layer 212 may be removed simultaneously by a wet etching process, thereby simplifying a manufacturing process of the semiconductor structure. When the second support layer 213 is remained on the side walls of the respective etching windows 26, a structure after the first sacrificial layer 212 and the protective layer 25 are synchronously removed is as illustrated in FIG. 2G. A person skilled in the art would also remove the second support layer 213 remained on the side walls of the respective etching windows 26 after removing the first sacrificial layer 212 and the protective layer 25 according to practical requirements to finally obtain a structure illustrated in FIG. 2H.

Optionally, the protective layer 25 and the first sacrificial layer 212 adopt different materials. The specific step of removing all the sacrificial layers and all the protective layers includes the following operations.

The first sacrificial layer 212 is removed to expose the first support layer 211.

The protective layer 25 is removed to expose the lower electrode layer 23.

In order to improve the protective effect of the protective layer 25 on the lower electrode layer 23, an etching selectivity between the protective layer 23 and the support layer is optionally greater than 3.

Optionally, the protective layer 23 adopts an oxide material and the support layer adopts a nitride material.

Optionally, a thickness of the protective layer 25 is smaller than ½ of a diameter of the capacitor hole 22 in a radial direction of the capacitor hole 22.

Specifically, the thickness of the protective layer 25 is smaller than ½ of the diameter of the capacitor hole 22, i.e. the capacitor hole 22 is not filled with the protective layer 25, so that the protective layer 25 can be subsequently removed sufficiently to avoid residue of the protective layer 25 inside the capacitor holes 22. The thickness of the protective layer 25 should also be smaller than ½ of a width of a gap region 24 between the adjacent capacitor holes 22, i.e. the gap region 24 between the adjacent capacitor holes 22 is not filled with the protective layer 25, so that the second support layer 213 can subsequently be opened by a directional etching process.

Optionally, after exposing the lower electrode layer 23, the method for forming the semiconductor structure further includes the following steps.

A dielectric layer covering a surface of the lower electrode layer 23 is formed.

An upper electrode layer covering a surface of the dielectric layer is formed.

Specifically, the dielectric layer preferably adopts a material having a high dielectric constant. The upper electrode layer and the lower electrode layer 23 may adopt the same material, e.g., titanium nitride.

Furthermore, the present specific embodiment also provides a semiconductor structure. The semiconductor structure provided by the present specific embodiment may be formed by the method for forming the semiconductor structure as illustrated in FIGS. 1 and 2A-2H. A schematic view of the semiconductor structure provided by the present specific embodiment may be seen in FIGS. 2G and 2H. As illustrated in FIGS. 2A-2H, the semiconductor structure provided by the present specific embodiment includes: a substrate 20, a laminated structure 21, a plurality of capacitor holes 22, and a plurality of lower electrode layers 23.

The substrate 20 has a plurality of capacitor contacts 201 therein.

The laminated structure 21 is disposed on a surface of the substrate 20, and includes a plurality of support layers stacked along a direction perpendicular to the substrate 20.

The plurality of capacitor holes 22 penetrate through the laminated structure 21 along the direction perpendicular to the substrate 20 and expose the plurality of capacitor contacts 201.

The plurality of lower electrode layers 23 cover inner walls of the plurality of capacitor holes 22. An etching window 26 is provided between at least two adjacent lower electrode layers 23, has part of the support layer connected to the lower electrode layers 23 on a side wall, and is communicated with a gap region 24 between the two adjacent lower electrode layers 23.

Optionally, the laminated structure 21 includes a first support layer 211, a second support layer 213, and a third support layer 215.

The first support layer 211 is disposed on the surface of the substrate 20.

The second support layer 213 is disposed above the first support layer 211.

The third support layer 215 is disposed above the second support layer 213.

Optionally, the etching windows 26 is disposed in the second support layer 213, and has part of the second support layer 213 connected to the lower electrode layer 23 on the side wall.

Optionally, a thickness of the second support layer 213 on the side wall of the etching window 26 is smaller than ½ of a diameter of the capacitor hole 22 in a radial direction of the capacitor hole 22.

Optionally, the semiconductor structure further includes a dielectric layer and an upper electrode layer.

The dielectric layer covers surfaces of the lower electrode layer 23 and the laminated structure 21.

The upper electrode layer covers a surface of the dielectric layer.

According to the semiconductor structure and the forming method thereof provided by the present specific embodiment, before the support layer in the laminated structure is opened, the surface of the formed lower electrode layer is covered with the protective layer, so that the damage to the lower electrode layer in the process of opening the support layer is avoided, the defects in the lower electrode layer are avoided, the performance stability of the lower electrode layer is ensured, and the reliability of the semiconductor structure is improved.

The foregoing is merely a preferred embodiment of the present disclosure, it should be noted that numerous modifications and adaptations may be devised by those of ordinary skill in the art without departing from the principle of the present disclosure. Such modifications and adaptations are to be considered within the protection scope of the present disclosure.

What is claimed is:

1. A method for forming a semiconductor structure, comprising steps of:
forming a base comprising a substrate, capacitor contacts in the substrate, a laminated structure disposed on a surface of the substrate and, capacitor holes penetrating through the laminated structure and exposing the respective capacitor contacts, and a lower electrode layer covering inner walls of the capacitor holes; the laminated structure comprising a plurality of support layers and at least one sacrificial layer which are alternately stacked along a direction perpendicular to the substrate;
forming a protective layer covering a surface of the lower electrode layer;
etching part of the support layer to expose the sacrificial layer; and
removing all the sacrificial layers and all the protective layer to expose the lower electrode layer.

2. The method for forming the semiconductor structure of claim 1, wherein the step of forming the base comprises:
providing a substrate having a plurality of capacitor contacts therein;
forming a laminated structure on a surface of the substrate, the laminated structure comprising a first support layer, a first sacrificial layer, a second support layer, a second sacrificial layer, and a third support layer which are sequentially stacked along a direction perpendicular to the substrate;
etching the laminated structure to form capacitor holes penetrating through the laminated structure along the direction perpendicular to the substrate and exposing the respective capacitor contacts; and
forming a lower electrode layer covering inner walls of the capacitor holes.

3. The method for forming the semiconductor structure of claim 2, wherein after said forming the lower electrode layer covering inner walls of the capacitor holes, the method further comprises steps of:
etching part of the third support layer to expose the second sacrificial layer; and
removing the second sacrificial layer to expose part of the second support layer.

4. The method for forming the semiconductor structure of claim 3, wherein the step of forming the protective layer covering the surface of the lower electrode layer comprises:
depositing protective materials on surfaces of the lower electrode layer, the remaining third support layer, and the exposed second support layer to form the protective layer.

5. The method for forming the semiconductor structure of claim 4, wherein the step of forming the protective layer covering a surface of the lower electrode layer further comprises:
forming the protective layer by adopting an in-situ atomic layer deposition process.

6. The method for forming the semiconductor structure of claim 3, wherein the step of exposing the part of the support layer comprises:
etching the protective layer between the adjacent capacitor holes to expose part of the second support layer.

7. The method for forming the semiconductor structure of claim 6, wherein the step of etching the protective layer between the adjacent capacitor holes comprises:
etching the protective layer between the adjacent capacitor holes along a direction perpendicular to the substrate.

8. The method for forming the semiconductor structure of claim 6, wherein after said exposing part of the second support layer, the method further comprises a step of:
etching the second support layer along a direction perpendicular to the substrate to expose the first sacrificial layer.

9. The method for forming the semiconductor structure of claim 8, wherein the step of etching the second support layer along the direction perpendicular to the substrate comprises:
etching the second support layer along a direction perpendicular to the substrate, forming etching windows exposing the first sacrificial layer in the second support layer, and remaining the second support layer on side walls of the etching windows.

10. The method for forming the semiconductor structure of claim 8, wherein a material of the protective layer is same as a material of the first sacrificial layer, and the step of removing all the sacrificial layers and all the protective layer comprises:
synchronously removing the first sacrificial layer and the protective layer.

11. The method for forming the semiconductor structure of claim 8, wherein a material of the protective layer is different from a material of the first sacrificial layer, and the step of removing all the sacrificial layers and all the protective layer comprises:
removing the first sacrificial layer to expose the first support layer; and
removing the protective layer to expose the lower electrode layer.

12. The method for forming the semiconductor structure of claim 1, wherein an etching selectivity between the protective layer and the support layer is greater than 3.

13. The method for forming the semiconductor structure of claim 1, wherein a material of the protective layer is an oxide material and a material of the support layer is a nitride material.

14. The method for forming the semiconductor structure of claim 1, wherein a thickness of the protective layer is smaller than ½ of a diameter of the capacitor hole in a radial direction of the capacitor hole.

15. The method for forming the semiconductor structure of claim 1, wherein after said exposing the lower electrode layer, the method further comprises steps of:
forming a dielectric layer covering a surface of the lower electrode layer; and
forming an upper electrode layer covering a surface of the dielectric layer.

16. A semiconductor structure, comprising:
a substrate having a plurality of capacitor contacts therein;
a laminated structure on a surface of the substrate, the laminated structure comprising a plurality of support layers stacked along a direction perpendicular to the substrate;
a plurality of capacitor holes, penetrating through the laminated structure along the direction perpendicular to the substrate and exposing the respective capacitor contacts; and
a plurality of lower electrode layers, covering inner walls of the respective capacitor holes; an etching window being provided between at least two adjacent lower electrode layers, the etching window having part of the support layer connected to the lower electrode layers on a side wall of the etching window, and the etching window being communicated with a gap region between the two adjacent lower electrode layers.

17. The semiconductor structure of claim 16, wherein the laminated structure comprises:
a first support layer disposed on the surface of the substrate;
a second support layer disposed above the first support layer; and
a third support layer disposed above the second support layer.

18. The semiconductor structure of claim 17, wherein the etching window is disposed in the second support layer, and has part of the second support layer connected to the lower electrode layer on the side wall of the etching window.

19. The semiconductor structure of claim 18, wherein a thickness of the second support layer on the side wall of the etching window is smaller than ½ of a diameter of the capacitor hole in a radial direction of the capacitor hole.

20. The semiconductor structure of claim 16, further comprising:
a dielectric layer covering surfaces of the lower electrode layers and the laminated structure; and
an upper electrode layer covering a surface of the dielectric layer.
